(19) United States
(12) Patent Application Publication
(10) Pub. No.: US 2026/0150599 A1
(43) Pub. Date: May 28, 2026

(54) DIRECT BACKSIDE CONTACT WITH DOUBLE ETCH STOP LAYER

(71) Applicant: International Business Machines Corporation, Armonk, NY (US)

(72) Inventors: Xiaoming Yang, Clifton Park, NY (US); Mahender Kumar, Clifton Park, NY (US); Reinaldo Vega, Mahopac, NY (US); Minhaz Abedin, Delmar, NY (US); Ruilong Xie, Niskayuna, NY (US); HUIMEI ZHOU, Albany, NY (US); Ravikumar Ramachandran, Pleasantville, NY (US)

(21) Appl. No.: 18/963,710

(22) Filed: Nov. 28, 2024

(51) Int. Cl. H01L 21/306; H01L 21/283; H01L 23/522; H01L 29/06; H01L 29/417; H01L 29/423; H01L 29/45; H01L 29/66; H01L 29/775; H01L 29/786

(52) U.S. Cl. CPC H10P 50/00; H10D 30/6729; H10D 64/62; H10P 14/40; H10D 30/014; H10D 30/43; H10D 30/6735; H10D 30/6757; H10D 62/121; H10W 20/42

(57) ABSTRACT

Semiconductor devices having a direct backside contact are provided. In one aspect, a semiconductor device includes: at least one FET on a frontside of a wafer, where the wafer includes a semiconductor layer, and where a most backside-facing surface of the semiconductor layer is planar; and a backside contact disposed on the most backside-facing surface of the semiconductor layer, where the backside contact directly contacts source/drain regions of the at least one FET. A local wiring layer can be disposed on a most backside-facing surface of the backside contact. A method of fabricating the present semiconductor devices is also provided.

### BACKGROUND

The present invention relates generally to the electrical, electronic and computer arts and, more particularly, to semiconductor devices having a backside power distribution network direct backside contact, and techniques for fabrication thereof using double etch stop layers.

With traditional semiconductor device architectures, both signal and power networks are often located on the frontside of a semiconductor wafer. However, with more complex circuit designs, space on the frontside of the semiconductor wafer is at a premium. As such, backside power distribution networks have been implemented.

As its name implies, a backside power distribution network provides power interconnections on the backside of a wafer. Relocating the power interconnections to the backside of the wafer frees up valuable space on the frontside of the wafer for other semiconductor device components, including signal connections.

### BRIEF SUMMARY

Principles of the invention provide semiconductor devices having a backside power distribution network direct backside contact fabricated using double etch stop layers. In one aspect, a semiconductor device is provided. The semiconductor device includes: at least one field-effect transistor (FET) on a frontside of a wafer, where the wafer includes a semiconductor layer, and where a most backside-facing surface of the semiconductor layer is planar; and a backside contact disposed on the most backside-facing surface of the semiconductor layer, where the backside contact directly contacts source/drain regions of the at least one FET.

In another aspect, another semiconductor device is provided. The semiconductor device includes: at least one FET on a frontside of a wafer, where the wafer includes a semiconductor layer; a backside contact disposed on the semiconductor layer, where a most backside-facing surface of the backside contact is planar, and where the backside contact directly contacts source/drain regions of the at least one FET; and a local wiring layer disposed on the most backside-facing surface of the backside contact.

In yet another aspect, a method of fabricating a semiconductor device is provided. The method includes: forming at least one FET on a frontside of a wafer, where the wafer includes: a substrate, a first etch stop layer disposed on the substrate, a first semiconductor layer disposed on the first etch stop layer, a second etch stop layer disposed on the first semiconductor layer, and a second semiconductor layer disposed on the second etch stop layer; performing an etch from a backside of the wafer to remove the substrate, stopping on the first etch stop layer; removing the first etch stop layer; performing another etch from the backside of the wafer to remove the first semiconductor layer, stopping on the second etch stop layer; removing the second etch stop layer to expose a most backside-facing surface of the second semiconductor layer which is planar; and forming a backside contact on the most backside-facing surface of the second semiconductor layer which directly contacts source/drain regions of the at least one FET.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-31 are views of a semiconductor device having a backside power distribution network and direct backside contacts with double etch stop layers at different steps in a fabrication process according to one or more embodiments of the present invention, where FIG. 1 is a top-down view and the remaining figures are X, Y1 or Y2 cross-sectional views; and

FIGS. 32-43 are X, Y1 or Y2 cross-sectional views of another semiconductor device having a backside power distribution network and direct backside contacts with double etch stop layers at different steps in a fabrication process according to one or more alternative embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor device (e.g., semiconductor device 1000, semiconductor device 1000′, etc.) is provided. The semiconductor device includes: at least one field-effect transistor (FET) (e.g., FET 1002a, FET 1002b, etc.) on a frontside of a wafer (e.g., wafer 1001), where the wafer includes a semiconductor layer (e.g., second semiconductor layer 1001e), and where a most backside-facing surface of the semiconductor layer is planar; and a backside contact (e.g., backside contact 26004) disposed on the most backside-facing surface of the semiconductor layer, where the backside contact directly contacts source/drain regions (e.g., source/drain regions 1010a and 1010b) of the at least one FET.

In another aspect, another semiconductor device (e.g., semiconductor device 1000, semiconductor device 1000′, etc.) is provided. The semiconductor device includes: at least one FET (e.g., FET 1002a, FET 1002b, etc.) on a frontside of a wafer (e.g., wafer 1001), where the wafer includes a semiconductor layer (e.g., second semiconductor layer 1001e); a backside contact (e.g., backside contact 26004) disposed on the semiconductor layer, where a most backside-facing surface of the backside contact is planar, and where the backside contact directly contacts source/drain regions (e.g., source/drain regions 1010a and 1010b) of the at least one FET; and a local wiring layer (e.g., local wiring layer 29004) disposed on the most backside-facing surface of the backside contact.

In yet another aspect, a method of fabricating a semiconductor device (e.g., semiconductor device 1000, semiconductor device 1000′, etc.) is provided. The method includes: forming at least one (e.g., FET 1002a, FET 1002b, etc.) on a frontside of a wafer (e.g., wafer 1001), where the wafer includes: a substrate (e.g., substrate 1001a), a first etch stop layer (e.g., first etch stop layer 1001b) disposed on the substrate, a first semiconductor layer (e.g., first semiconductor layer 1001c) disposed on the first etch stop layer, a second etch stop layer (e.g., second etch stop layer 1001d) disposed on the first semiconductor layer, and a second semiconductor layer (e.g., second semiconductor layer 1001e) disposed on the second etch stop layer; performing an etch from a backside of the wafer to remove the substrate, stopping on the first etch stop layer; removing the first etch stop layer; performing another etch from the backside of the wafer to remove the first semiconductor layer, stopping on the second etch stop layer; removing the second etch stop layer to expose a most backside-facing surface of the second semiconductor layer which is planar; and forming a backside contact (e.g., backside contact 26004) on the most backside-facing surface of the second semiconductor layer which directly contacts source/drain regions (e.g., source/drain regions 1010a and 1010b) of the at least one FET.

Techniques as disclosed herein can provide substantial beneficial technical effects. Some embodiments may not have these potential advantages and these potential advantages are not necessarily required of all embodiments. By way of example only and without limitation, one or more embodiments of the present semiconductor devices can provide one or more of:
Implementation of double etch stop layers which enable the formation of a backside power distribution network having direct backside contacts;
Where a first one of the double etch stop layers serves to protect the underlying wafer and optional placeholder;
While a second one of the double etch stop layers enables the formation of local wiring; and
Where the direct backside contacts and local wiring have sharper, more well-defined features using the present double etch stop layers.

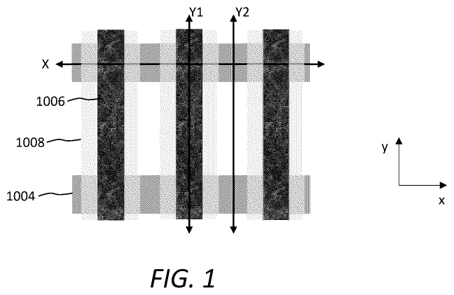

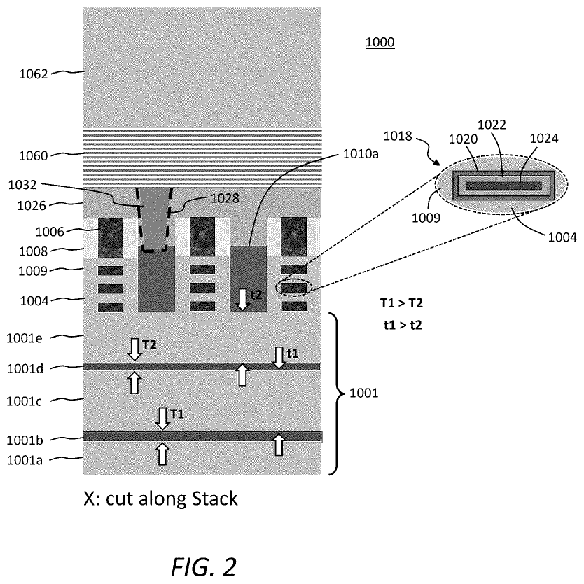

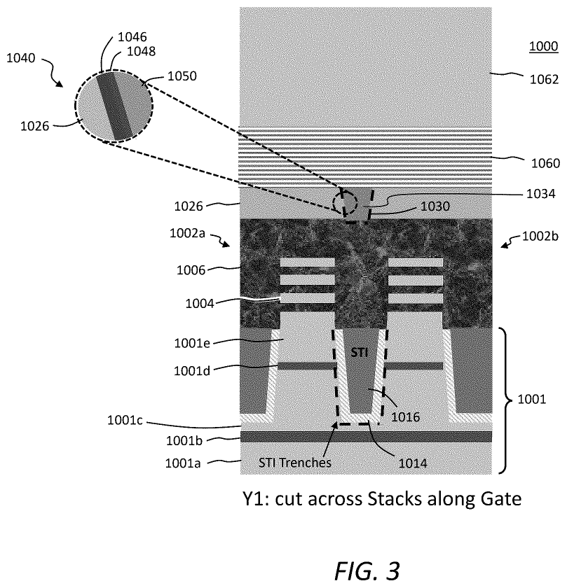

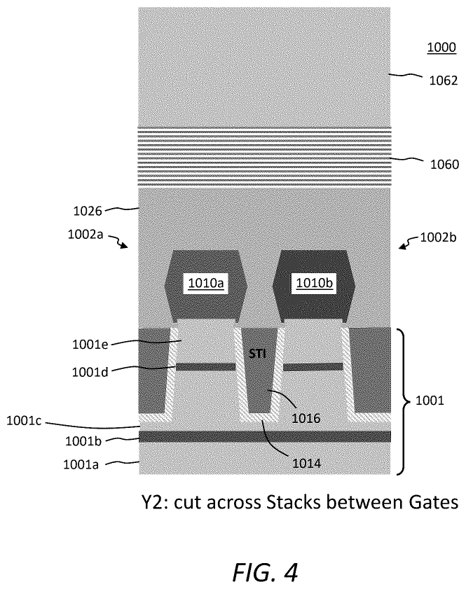

An exemplary methodology for fabricating a semiconductor device 1000 in accordance with the present techniques is now described by way of reference to FIGS. 1-31. For instance, referring to FIG. 1 (a top-down view), FIG. 2 (an X cross-sectional view), FIG. 3 (a Y1 cross-sectional view) and FIG. 4 (a Y2 cross-sectional view), the process begins with the formation of at least one field-effect transistor (FET), e.g., (first) FET 1002a, (second) FET 1002b, etc., on a frontside of a wafer 1001. Whenever reference is made herein to the ‘frontside’ or ‘backside’ of the wafer 1001, as the case may be, it is to be understood that the same orientations apply to the resulting semiconductor device 1000 (or semiconductor device 1000′, below). Namely, the frontside and backside of the wafer 1001 correspond to the frontside and backside of the semiconductor device 1000 (or semiconductor device 1000′), respectively.

According to an exemplary embodiment, each FET 1002a, 1002b, etc. includes a stack of active layers 1004 that serve as a channel, a gate 1006 on the channel that surrounds each of the active layers in a gate-all-around or GAA configuration, and source/drain regions 1010a and 1010b at opposite ends of the active layers 1004 (channel) and offset from the gate 1006 by gate spacers 1008 and inner spacers 1009. An interlayer dielectric 1026 is disposed over the FETs 1002a, 1002b, etc. Contacts 1032 to the source/drain regions 1010a and 1010b (also referred to herein as “source/drain contacts”) and contacts 1034 to the gates 1006 (also referred to herein as “gate contacts”) are present in the interlayer dielectric 1026. A back end of line layer 1060 is formed on the interlayer dielectric 1026, and the back end of line layer 1060 is bonded to a carrier wafer 1062.

As shown particularly in FIG. 1, semiconductor device 1000 can include multiple stacks of the active layers 1004 and multiple gates 1006, oriented orthogonal to one another, and extending arbitrarily along an X-direction and a Y-direction, respectively. Accordingly, the X cross-sectional views provided herein represent cuts through the semiconductor device 1000 (or semiconductor device 1000′, below) in the X-direction, i.e., along one of the stacks of active layers 1004. The Y1 cross-sectional views represent first cuts through the semiconductor device 1000 (or semiconductor device 1000′) in the Y-direction, i.e., across the stacks of active layers 1004 along one of the gates 1006. The Y2 cross-sectional views represent second cuts through the semiconductor device 1000 (or semiconductor device 1000′) in the Y-direction, i.e., across the stacks of active layers 1004 between two of the gates 1006. It is notable that, for ease and clarity of depiction, not all of the features of the semiconductor device 1000 (or semiconductor device 1000′) are shown in FIG. 1. In FIG. 1 for instance, structures such as the back end of line layer 1060, carrier wafer 1062, etc. (see below) are not included in order to show the orientation of the stacks of active layers 1004 and the gates 1006.

As highlighted above, the present techniques employ a unique double etch stop layer design to enable the formation of a backside power distribution network having direct backside contacts. Thus, according to an exemplary embodiment, the wafer 1001 includes a substrate 1001a, a first etch stop layer 1001b disposed directly on the substrate 1001a, a first semiconductor layer 1001c disposed directly on the first etch stop layer 1001b, a second etch stop layer 1001d disposed directly on the first semiconductor layer 1001c, and a second semiconductor layer 1001e disposed directly on the second etch stop layer 1001d. As such, with this configuration of the wafer 1001, the first etch stop layer 1001b is present as an interlayer between the substrate 1001a and the first semiconductor layer 1001c. Accordingly, the first etch stop layer 1001b may also be referred to herein as a ‘first interlayer.’ Similarly, the second etch stop layer 1001d is present as another interlayer between the first semiconductor layer 1001c and the second semiconductor layer 1001e. Accordingly, the second etch stop layer 1001d may also be referred to herein as a ‘second interlayer.’

In an exemplary embodiment, the first etch stop layer 1001b (i.e., first interlayer) has a thickness T1 (e.g., T1 is from about 15 nanometers (nm) to about 25 nm, preferably about 20 nm), the second etch stop layer 1001d (i.e., second interlayer) has a thickness T2 (e.g., T2 is from about 5 nm to about 15 nm, preferably about 10 nm), and T1>T2. Further in that regard, in an exemplary embodiment, the first semiconductor layer 1001 c has a thickness t1 (e.g., t1 is from about 30 nm to about 40 nm, preferably about 35 nm), the second semiconductor layer 1001 e has a thickness t2 (e.g., t2 is from about 25 nm to about 35 nm, preferably about 30 nm), and t1>t2.

As will be described in detail below, processing for the direct backside contact and local wiring will be performed from a backside of the wafer 1001. To serve as etch stops during that backside processing, the first etch stop layer 1001b (i.e., first interlayer) and the second etch stop layer 1001d (i.e., second interlayer) are formed from materials that are resistant to the etching processes being used to pattern the immediately preceding/underlying layer from the backside of the wafer 1001. For instance, the first etch stop layer 1001b (i.e., first interlayer) formed from a semiconductor material such as SiGe or an oxide material such as silicon dioxide (SiO₂) would be resistant to an etching process used to pattern the underlying substrate 1001a when the substrate 1001a is, e.g., Si, since the first etch stop layer 1001b (i.e., first interlayer) and the substrate 1001a are different materials. Similarly, the second etch stop layer 1001d (i.e., second interlayer) formed, e.g., from SiGe or SiO₂ would be resistant to an etching process used to pattern the underlying first semiconductor layer 1001c when the first semiconductor layer 1001c is, e.g., Si, since the second etch stop layer 1001d (i.e., second interlayer) and the first semiconductor layer 1001c are different materials.

In that regard, the substrate 1001a may be a bulk semiconductor wafer, such as a bulk silicon (Si) wafer, and the first etch stop layer 1001b (i.e., first interlayer) may be formed from silicon germanium (SiGe) that is epitaxially grown from the (Si) substrate 1001a. The first semiconductor layer 1001c (e.g., Si) can then be epitaxially grown from the first etch stop layer 1001b (i.e., first interlayer). Similarly, the second etch stop layer 1001d (i.e., second interlayer) may be formed from SiGe that is epitaxially grown from the (Si) first semiconductor layer 1001c, and the second semiconductor layer 1001e (e.g., Si) can then be epitaxially grown from the second etch stop layer 1001d (i.e., second interlayer). Alternatively, embodiments are also contemplated herein where the first etch stop layer 1001b (i.e., first interlayer) and/or the second etch stop layer 1001d (i.e., second interlayer) is an oxide layer.

As shown in the figures, the active layers 1004 are oriented horizontally (i.e., stacked) one on top of another on wafer 1001. In one exemplary embodiment, the active layers 1004 (and below-references sacrificial layers) are nanosheets. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa.

As would be apparent to one of ordinary skill in the art, the active layers 1004 can initially be separated by alternating sacrificial layers (not shown as they are no longer present at this point in the process flow). The term “sacrificial” as used herein refers to a material or structure that is used in one part of the process, and then later removed, in whole or in part, during fabrication of the semiconductor device 1000/1000′. These sacrificial layers can then be removed in order to “release” the active layers 1004 from the stack, thereby enabling the subsequently-formed gates 1006 to surround a portion of each of the active layers 1004 in a GAA configuration.

As such, the materials employed for the sacrificial layers and the active layers 1004 are such that the sacrificial layers can be removed selective to the active layers 1004 during fabrication. For instance, according to an exemplary embodiment, the sacrificial layers are each formed from SiGe, while the active layers 1004 are formed from Si. Etchants such as wet hot SC1, vapor phase hydrogen chloride (HCl), vapor phase chlorine trifluoride (ClF₃) and other reactive clean processes (RCP) are selective for etching of SiGe versus Si. This is, however, only one exemplary combination of sacrificial/active material that may be employed in accordance with the present techniques. For instance, by way of example only, the opposite configuration can instead be employed where the sacrificial layers are each formed from Si, and the active layers 1004 are each formed from SiGe.

It is notable that the number of active layers 1004 shown in the figures is provided merely as an example to illustrate the present techniques. For instance, embodiments are contemplated herein where more or fewer active layers 1004 are present than shown. According to an exemplary embodiment, each of the active layers 1004 has a thickness of from about 6 nm to about 25 nm.

Shallow trench isolation (STI) regions are present in the wafer 1001 in between the stacks of active layers 1004. As shown, for example, in FIG. 3 and FIG. 4, each of these STI regions includes a liner 1014 disposed into and lining STI trenches in the wafer 1001 in between the stacks of active layers 1004, and a dielectric 1016 disposed on the liner 1014. Suitable materials for the liner 1014 include, but are not limited to, a thermal oxide or silicon nitride (SiN). A process such as chemical vapor deposition (CVD), atomic layer deposition (ALD), or physical vapor deposition (PVD) can be used to deposit the liner 1014 into the STI trenches. According to an exemplary embodiment, the dielectric 1016 is an oxide (which may also be generally referred to herein as an “STI oxide”). Suitable STI oxides include, but are not limited to, oxide low-κ materials such as silicon oxide (SiOx) and/or oxide ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH). A process such as CVD, ALD or PVD can be used to deposit the dielectric 1016 (e.g., STI oxide) onto the liner 1014, after which the dielectric 1016 can be planarized using a process such as chemical-mechanical polishing or CMP, and then recessed using a dry or wet etch process.

According to an exemplary embodiment, the source/drain regions 1010a and 1010b are each formed from an n-type or p-type in-situ doped (i.e., during growth) or ex-situ doped (e.g., via ion implantation) epitaxial material such as epitaxial Si, epitaxial SiGe, etc. Suitable p-type dopants include, but are not limited to, boron (B). Suitable n-type dopants include, but are not limited to, phosphorous (P) and/or arsenic (As). For instance, by way of example only, in one exemplary embodiment, the source/drain regions 1010a are formed from boron-doped SiGe (SiGe:B) and the source/drain regions 1010b are formed from phosphorous-doped Si (Si:P), or vice versa.

In one illustrative, non-limiting example, the gates 1006 are replacement metal gates formed using a gate-last process. As would be apparent to one of ordinary skill in the art, a gate-last process involves forming sacrificial gates (not shown as they are no longer present at this point in the process flow) of, e.g., polysilicon and/or amorphous silicon, early on in the process which serve as placeholders, and enable the placement of other components such as the source/drain regions 1010a and 1010b. Advantageously, use of a gate-last process avoids exposing the replacement metal gate materials such as high-κ dielectrics to potentially damaging conditions such as the high temperatures experienced during source/drain region formation. Accordingly, following placement of the source/drain regions, the sacrificial gates are then removed and replaced with the final or “replacement” gates of the device. When these replacement gates are metal, they are also referred to herein as “replacement metal gates.”

For instance, referring to magnified view 1018 in FIG. 2, in this non-limiting example gates 1006 include a (conformal) gate dielectric 1020 disposed on the active layers 1004/spacers 1008/inner spacers 1009, at least one workfunction-setting metal 1022 disposed on the gate dielectric 1020, and an optional (low-resistance) fill metal 1024 disposed on the workfunction-setting metal(s) 1022. According to an exemplary embodiment, gate dielectric 1020 is a high-κ material. The term “high-κ,” as used herein, refers to a material having a relative dielectric constant κ which is much higher than that of silicon dioxide (e.g., a dielectric constant κ=25 for hafnium oxide (HfO₂) rather than 4 for SiO₂). Suitable high-κ gate dielectrics include, but are not limited to, hafnium oxide (HfO₂) and/or lanthanum oxide (La₂O₃). A process such as CVD, ALD, or PVD can be employed to deposit the gate dielectric 1020. According to an exemplary embodiment, gate dielectric 1020 has a thickness of from about 1 nm to about 5 nm. A reliability anneal can be performed following deposition of gate dielectric 1020. In one exemplary embodiment, the reliability anneal is performed at a temperature of from about 500° C. to about 1200° C., for a duration of from about 1 nanosecond to about 30 seconds. Preferably, the reliability anneal is performed in the presence of an inert gas such as, but not limited to, nitrogen.

The at least one workfunction-setting metal 1022 can include an n-type workfunction-setting metal and/or a p-type workfunction-setting metal. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). Suitable p-type workfunction-setting metals include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n-and p-type workfunction-setting metals given above. A process such as CVD, ALD or PVD can be employed to deposit the workfunction-setting metal(s) 1022, after which the metal overburden can be removed using a process such as CMP.

The optional fill metal 1024 can be used to fill in any remaining spaces in the gates 1006. Suitable (low-resistance) fill metals 1024 include, but are not limited to, W, cobalt (Co), ruthenium (Ru) and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

The FETs 1002a, 1002b, etc. are buried in an interlayer dielectric 1026. Suitable interlayer dielectric 1026 materials include, but are not limited to, SiN, silicon oxycarbide (SiOC) and/or oxide low-κ materials such as SiOx and/or oxide ULK-ILD materials such as pSiCOH, which can be deposited onto the semiconductor device 1000 using a process such as CVD, ALD or PVD. Following deposition, the interlayer dielectric 1026 can be planarized using a process such as CMP.

Contact patterning and metallization are used to form contacts 1032 to the source/drain regions 1010a and 1010b and contacts 1034 to the gates 1006. Specifically, standard lithography and etching techniques are employed to pattern trenches 1028/1030 in the interlayer dielectric 1026 over the source/drain regions 1010a and 1010b/gates 1006, respectively. With standard lithography and etching techniques, a lithographic stack (not shown), e.g., photoresist/anti-reflective coating/organic planarizing layer, is used to pattern a hardmask (not shown) with the footprint and location of, in this case, the trenches 1028 and 1030. Suitable hardmask materials include, but are not limited to, silicon nitride (SiN), silicon dioxide (SiO₂) (including low temperature oxides or LTOs deposited at a temperature of from about 400° C. to about 450° C.), titanium nitride (TiN) and/or silicon oxynitride (SiON). An etch is then performed to transfer the pattern from the hardmask to the underlying materials. Suitable etching processes include, but are not limited to, directional (anisotropic) etching processes such as reactive ion etching. Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

Standard metallization processes can be employed to form the contacts 1032 to the source/drain regions 1010a and 1010b in the trenches 1028 and the contacts 1034 to the gates 1006 in the trenches 1030. For instance, referring to magnified view 1040 in FIG. 3, this metallization can include first depositing a silicide liner 1046 into and lining each of the trenches 1028 and 1030, depositing a metal adhesion layer 1048 onto the silicide liner 1046, and then depositing a fill metal 1050 onto the metal adhesion layer 1048. Suitable silicide liner 1046 materials include, but are not limited to, titanium (Ti), nickel (Ni) and/or nickel platinum (NiPt), which can be deposited using a process such as CVD, ALD or PVD. According to an exemplary embodiment, silicide liner 1046 has a thickness of from about 1 nm to about 5 nm. Suitable metal adhesion layer 1048 materials include, but are not limited to, TiN and/or TaN, which can be deposited onto the silicide liner 1046 using a process such as CVD, ALD or PVD. According to an exemplary embodiment, the metal adhesion layer 1048 has a thickness of from about 1 nm to about 5 nm. Suitable fill metals 1050 include, but are not limited to, W, Co, Ru and/or Al, which can be deposited onto the metal adhesion layer 1048 using a process such as CVD, ALD, PVD, sputtering, plating, evaporation, ion beam deposition, electron beam deposition, laser assisted deposition, chemical solution deposition, etc. Following deposition, the overburden can be removed using a process such as CMP.

Back end of line layer 1060 generally includes structures commonly formed in the back end of line during semiconductor device fabrication. Namely, in the back end of line, individual devices such as transistors get interconnected through a series of metal layers interspersed with dielectric material. For instance, conductive structures like vias and metal lines can be employed to connect a device to one or more other devices, to external connections, and the like, with the metal lines making lateral connections and the vias making vertical connections amongst different metallization levels. Standard metallization techniques can be employed to form the back end of line layer 1060. While the individual interconnects present in back end of line layer 1060 are not specifically shown in the figures, one skilled in the art would understand how such a back end of line layer 1060 is implemented for a given semiconductor device application.

Carrier wafer 1062 is bonded to a frontside of the wafer 1001 over the back end of line layer 1060. Suitable carrier wafers include, but are not limited to, silicon, silicon carbide and/or glass wafers. As will be described in detail below, the use of the carrier wafer 1062 will enable the wafer 1001 to be flipped, thereby permitting backside processing for the present direct backside contact and local wiring.

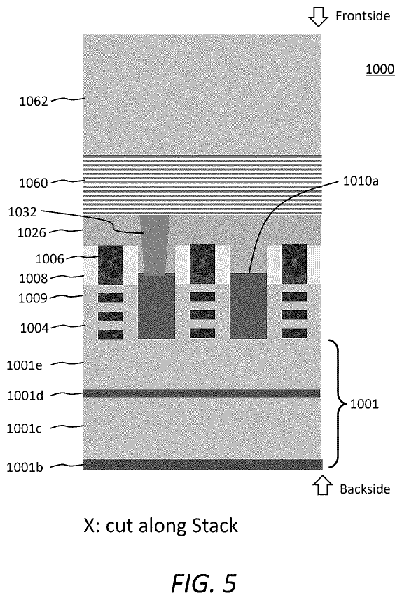

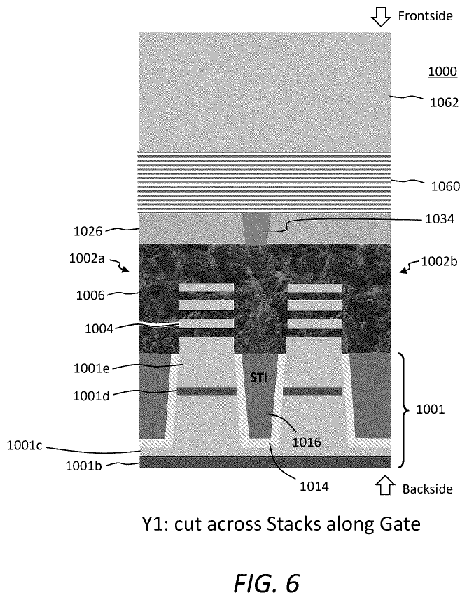

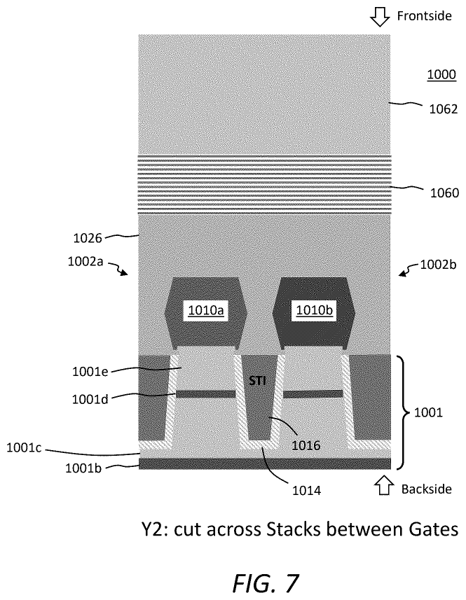

Referring to FIG. 5 (an X cross-sectional view), FIG. 6 (a Y1 cross-sectional view) and FIG. 7 (a Y2 cross-sectional view), an etch is next performed to remove the substrate 1001a, stopping on the first etch stop layer 1001b (i.e., first interlayer). It is notable that, prior to removing the substrate 1001a, the wafer 1001 is first flipped meaning that what was once at the bottom of wafer 1001 is now on the top, and vice versa. Doing so enables top-down processing to be performed on the backside of wafer 1001. However, for consistency, the figures themselves have not been flipped in the drawings with the express understanding that processes now being performed on the backside of wafer 1001 (see label) would in practice be performed from the top-down on a flipped wafer.

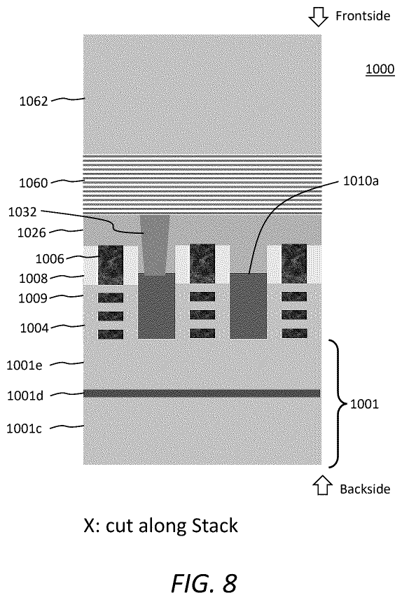

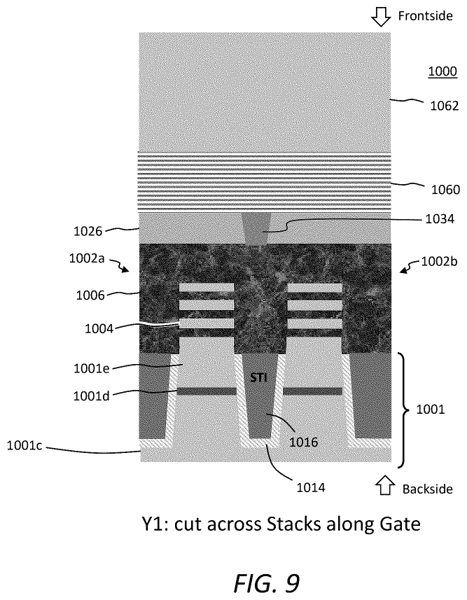

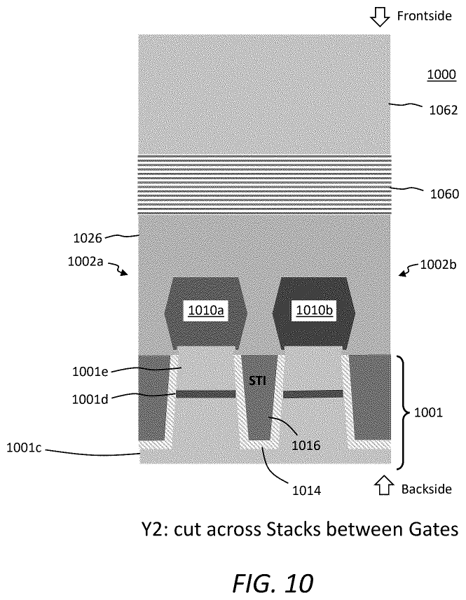

As provided above, the first etch stop layer 1001b (i.e., first interlayer) can be formed from SiGe or an oxide material, and the substrate 1001a can be formed from Si. In that case, an Si-selective etch can be used to remove the substrate 1001a. The first etch stop layer 1001b serves to protect the underlying first semiconductor layer 1001c and optional placeholder (see below) during removal of the substrate 1001a. Another, e.g., SiGe or oxide-selective, etch can then be performed in turn to remove the first etch stop layer 1001b (i.e., first interlayer). See FIG. 8 (an X cross-sectional view), FIG. 9 (a Y1 cross-sectional view) and FIG. 10 (a Y2 cross-sectional view)

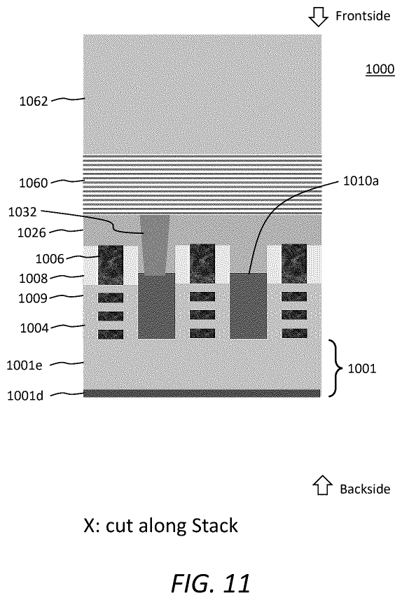

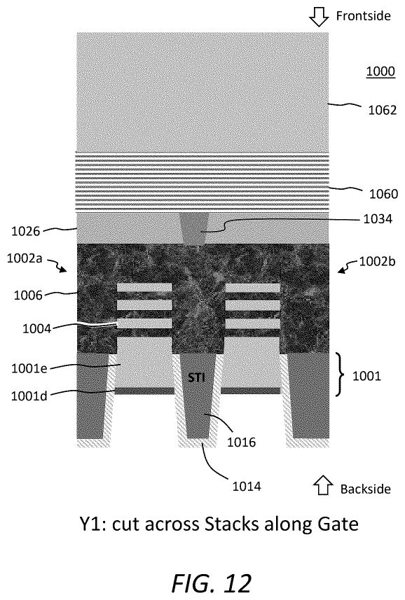

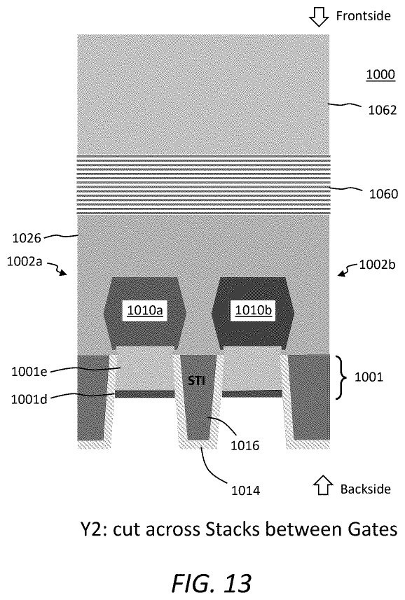

A similar process is then used to selectively remove the first semiconductor layer 1001c and the second etch stop layer 1001d (i.e., second interlayer). Namely, referring to FIG. 11 (an X cross-sectional view), FIG. 12 (a Y1 cross-sectional view) and FIG. 13 (a Y2 cross-sectional view), an etch is next performed from the backside of the wafer 1001 to remove the first semiconductor layer 1001c, stopping on the second etch stop layer 1001d (i.e., second interlayer). As provided above, the second etch stop layer 1001d (i.e., second interlayer) can be formed from SiGe or an oxide material, and the first semiconductor layer 1001c can be formed from Si. In that case, an Si-selective etch can be used to remove the first semiconductor layer 1001c. The second etch stop layer 1001d (i.e., second interlayer) serves to protect the underlying second semiconductor layer 1001e during removal of the first semiconductor layer 1001c which, as will be described in detail below, will enable the formation of local wiring.

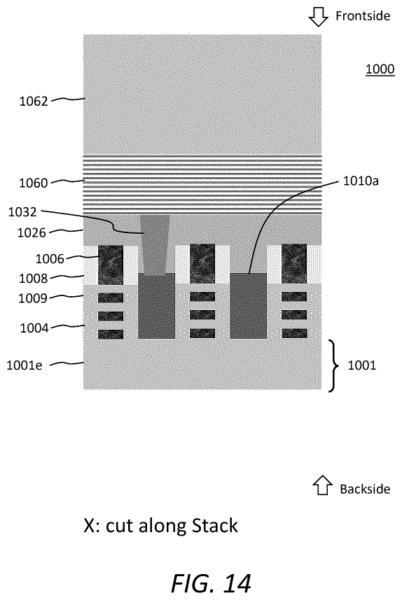

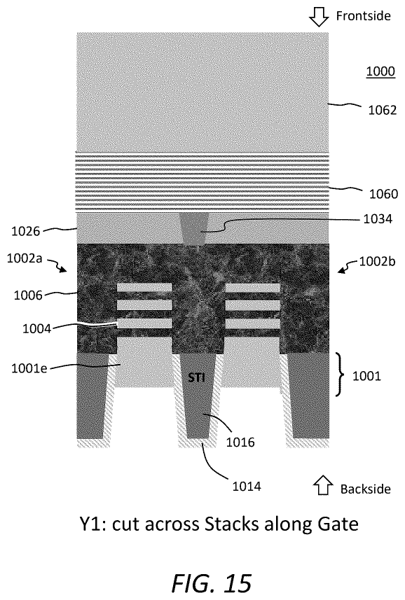

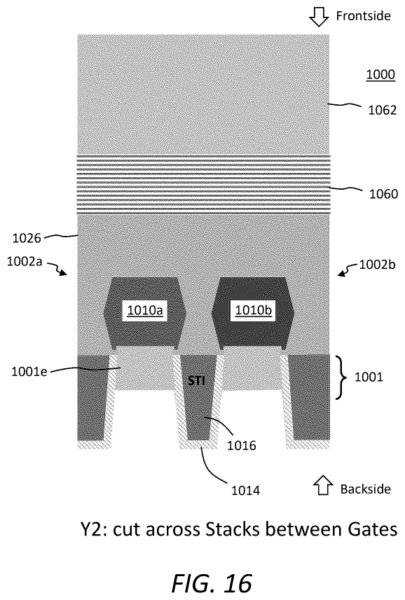

Another, e.g., SiGe or oxide-selective, etch can then be performed in turn to remove the second etch stop layer 1001d (i.e., second interlayer), thereby exposing a most backside-facing surface of the second semiconductor layer 1001e. See FIG. 14 (an X cross-sectional view), FIG. 15 (a Y1 cross-sectional view) and FIG. 16 (a Y2 cross-sectional view).

Advantageously, use of the present double etch stop layer provides some notable benefits. For instance, the first etch stop layer 1001b (i.e., first interlayer) enables the clean and effective removal of the substrate 1001a which represents a large bulk of the wafer 1001. This is done without affecting the underlying layers, including the second semiconductor layer 1001e which will remain throughout the direct backside contact and local wiring process. Namely, the second etch stop layer 1001d (i.e., second interlayer) enables further removal of the wafer 1001, leaving behind a well-defined second semiconductor layer 1001e (e.g., Si) of a consistent thickness across its length (e.g., of from about 25 nm to about 35 nm, preferably about 30 nm—see above) below the FETs 1002a, 1002b, etc. on the backside of the wafer 1001.

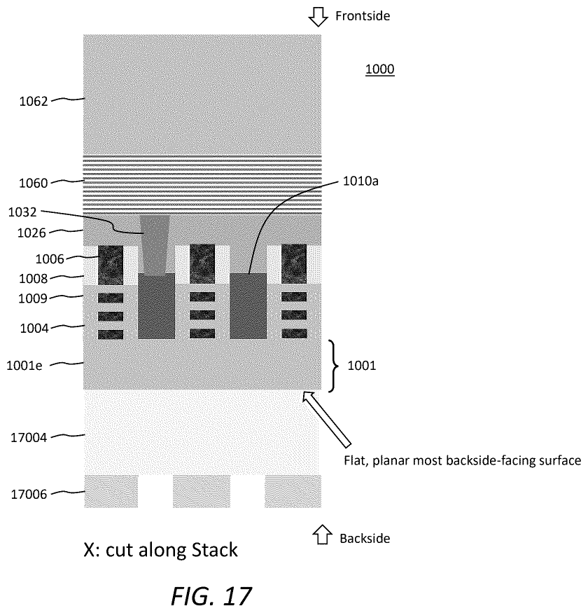

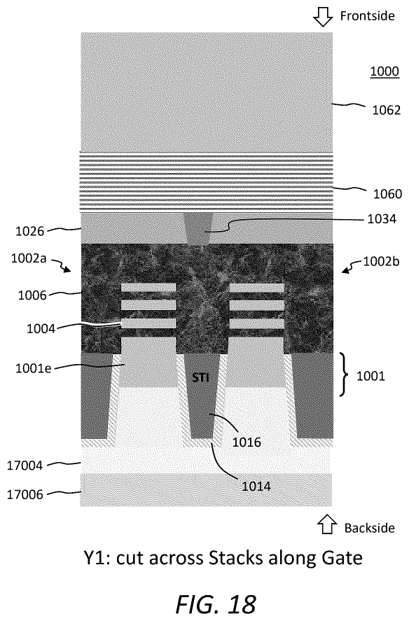

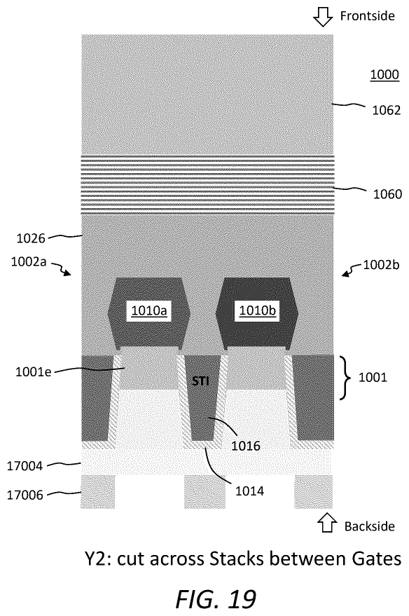

Referring to FIG. 17 (an X cross-sectional view), FIG. 18 (a Y1 cross-sectional view) and FIG. 19 (a Y2 cross-sectional view), the direct backside contact and local wiring process continues with the formation of a block mask 17004 over the second semiconductor layer 1001e on the backside of the wafer 1001, and the formation of a hardmask 17006 on the block mask 17004. Suitable materials for the block mask 17004 include, but are not limited to, organic planarizing layer or OPL materials, which can be deposited using a casting process such as spin-coating or spray casting. Notably, as shown in FIGS. 17-19 the block mask 17004 is deposited directly onto the most backside-facing surface (in this depiction the bottom-most surface) of the second semiconductor layer 1001e which is flat, i.e., planar.

Suitable hardmask 17006 materials were provided above. According to an exemplary embodiment, the hardmask 17006 is a low temperature oxide or LTO. As shown particularly in FIG. 17 and FIG. 19, the hardmask 17006 is patterned with the footprint and location of trenches 20004 (see below) that will be formed in the block mask 17004 and the second semiconductor layer 1001e.

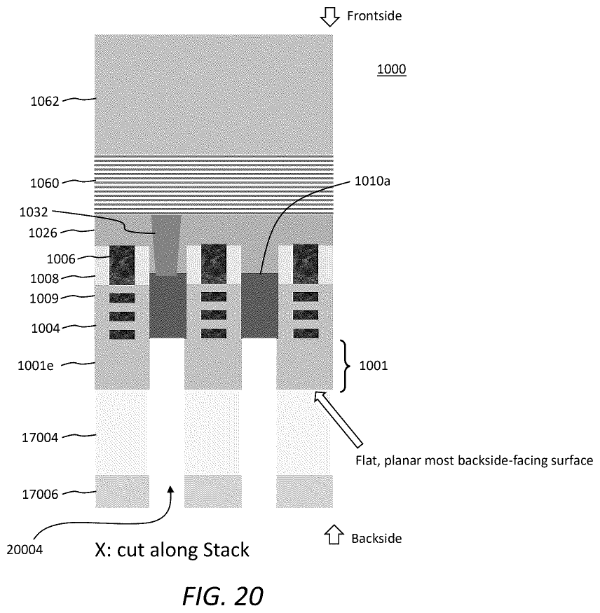

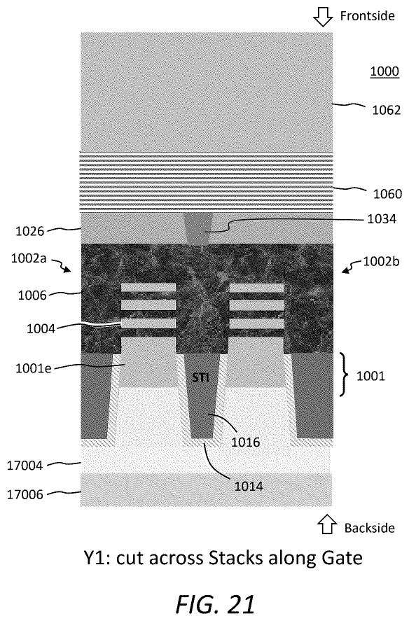

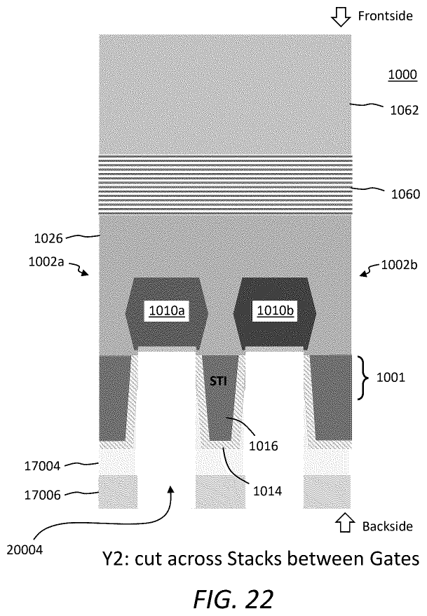

Namely, referring to FIG. 20 (an X cross-sectional view), FIG. 21 (a Y1 cross-sectional view) and FIG. 22 (a Y2 cross-sectional view), an etch is then performed to transfer the pattern from the hardmask 17006 to the block mask 17004 and, in turn, to the second semiconductor layer 1001e. Suitable etching processes include, but are not limited to, directional (anisotropic) etching processes such as reactive ion etching. Doing so results in the formation of trenches 20004 in the block mask 17004 and the second semiconductor layer 1001e which expose the source/drain regions 1010a and 1010b from the backside of the wafer 1001. Following etching of the trenches 20004, what remains of the hardmask 17006 and the block mask 17004 are then removed using, e.g., a process such as plasma ashing.

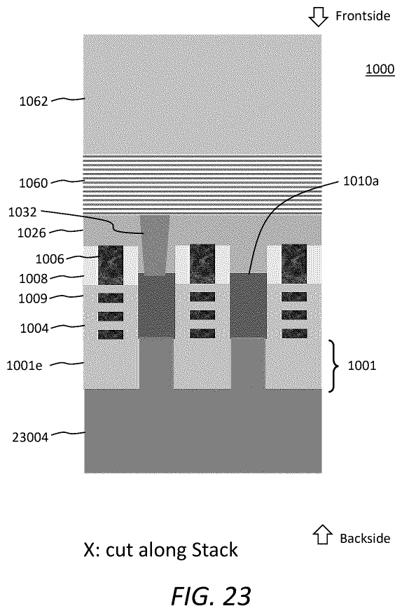

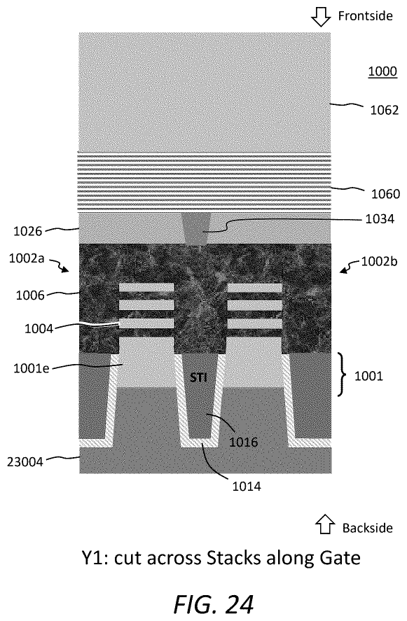

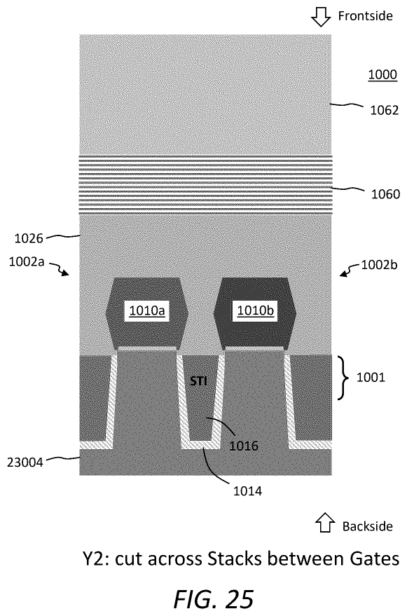

As will become apparent from the description that follows, the trenches 20004 will serve as the basis for forming backside contacts 26004 that directly contact the source/drain regions 1010a and 1010b from the backside of the wafer 1001. For instance, referring to FIG. 23 (an X cross-sectional view), FIG. 24 (a Y1 cross-sectional view) and FIG. 25 (a Y2 cross-sectional view), a contact metal 23004 is next deposited, from the backside of the wafer 1001, onto the second semiconductor layer 1001e and into and filling the trenches 20004. Suitable contact metals 23004 include, but are not limited to, W, Co, Ru and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

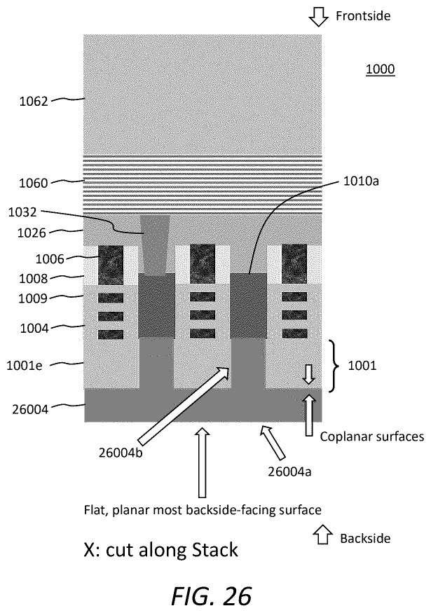

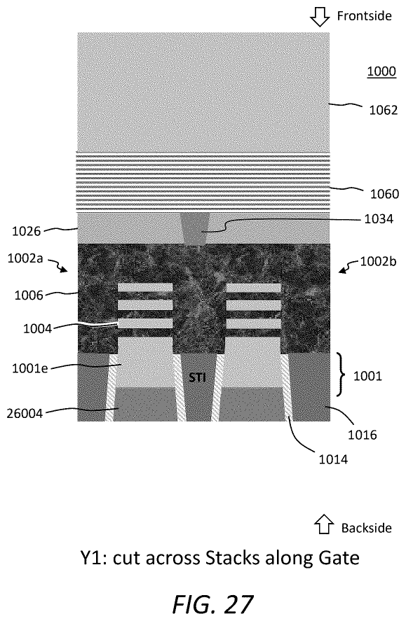

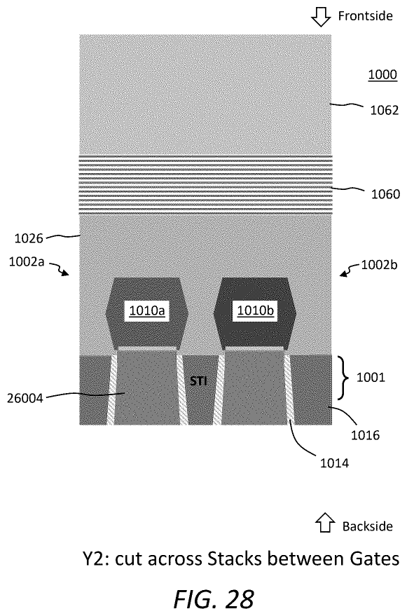

Referring to FIG. 26 (an X cross-sectional view), FIG. 27 (a Y1 cross-sectional view) and FIG. 28 (a Y2 cross-sectional view), following deposition, the contact metal 23004 can be planarized using a process such as CMP, resulting in the formation of backside contacts 26004 on the second semiconductor layer 1001e. As shown in FIGS. 26-28, the backside contacts 26004 directly contact the source/drain regions 1010a and 1010b from the backside of the wafer 1001. Namely, as shown particularly in FIG. 26, each of the backside contacts 26004 includes a first portion 26004a and second portions 26004b. According to an exemplary embodiment, a top surface of the first portion 26004a of each of the backside contacts 26004 directly contacts and is coplanar with the flat, planar most backside-facing surface (in this depiction the bottom-most surface) of the second semiconductor layer 1001e. As a result, the present backside contacts 26004 have sharper, more well-defined features. The second portions 26004b of each of the backside contacts 26004 (which are contiguous with the first portion 26004a) each directly contacts the source/drain regions 1010a and 1010b. With this configuration, a most backside-facing surface (in this depiction the bottom-most surface) of each of the backside contacts 26004 is flat, i.e., planar. It is on this flat/planar surface that local wiring is formed.

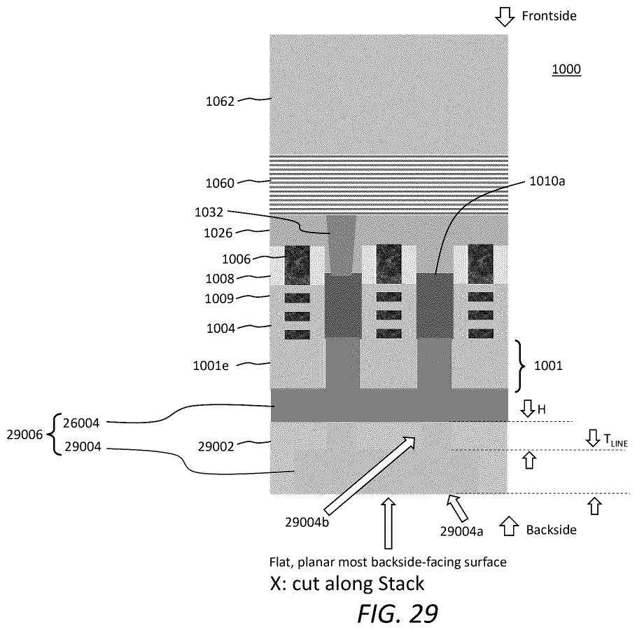

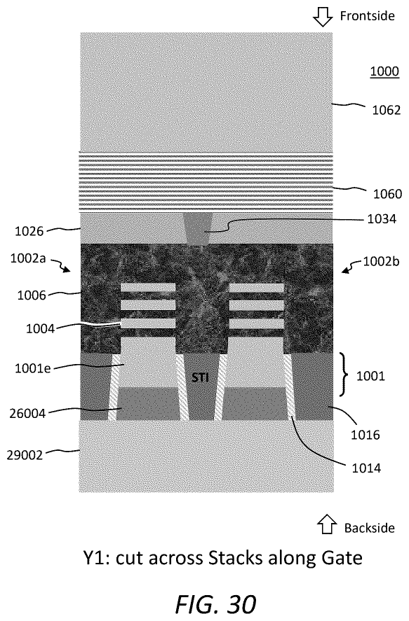

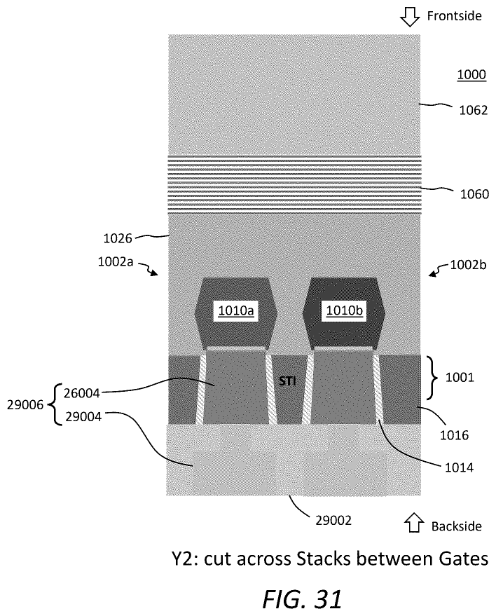

Namely, referring to FIG. 29 (an X cross-sectional view), FIG. 30 (a Y1 cross-sectional view) and FIG. 31 (a Y2 cross-sectional view), a local wiring layer 29004 is formed on the backside of the wafer 1001 over and directly contacting the backside contacts 26004 to complete the semiconductor device 1000. The backside contacts 26004 and the local wiring layer 29004 together form a backside power distribution network 29006 of the semiconductor device 1000 on the backside of the wafer 1001.

According to an exemplary embodiment, a so-called dual damascene process is used to form the local wiring layer 29004, whereby a dielectric 29002 is first deposited onto the backside of the wafer 1001 over the backside contacts 26004. Suitable dielectrics 29002 include, but are not limited to, oxide low-κ materials such as SiOx and/or oxide ULK-ILD materials, e.g., pSiCOH. A process such as CVD, ALD or PVD can be used to deposit the dielectric 29002, after which the dielectric 29002 can be planarized using a process such as CMP.

Standard lithography and etching techniques (see above) are then used to pattern features (e.g., trenches and/or vias) in the dielectric 29002. A metal (or combination of metals) is then deposited into and filling the features. Suitable metals include, but are not limited to, copper (Cu), Ru and/or Al which can be deposited using a process or combination of processes including, but not limited to, CVD, ALD, PVD, sputtering, plating, evaporation, ion beam deposition, electron beam deposition, laser assisted deposition, chemical solution deposition, etc. The metal overburden can then be removed using a process such as CMP.

As shown particularly in FIG. 29 and FIG. 30, the local wiring layer 29004 directly contacts the backside contacts 26004 from the backside of the wafer 1001. Namely, according to an exemplary embodiment, local wiring layer 29004 includes a metal line 29004a and conductive vias 29004b that interconnect metal line 29004a and the backside contacts 26004. More specifically, the conductive vias 29004b contact the flat, planar most backside-facing surface (in this depiction the bottom-most surface) of the backside contacts 26004. As a result, the present local wiring layer 29004 has sharper, more well-defined features. In one exemplary embodiment, metal line 29004a has a thickness T_{LINE} of from about 55 nm to about 65 nm, preferably about 60 nm, and the conductive vias 29004 b each have a height H of from about 35 nm to about 45 nm, preferably about 40 nm.

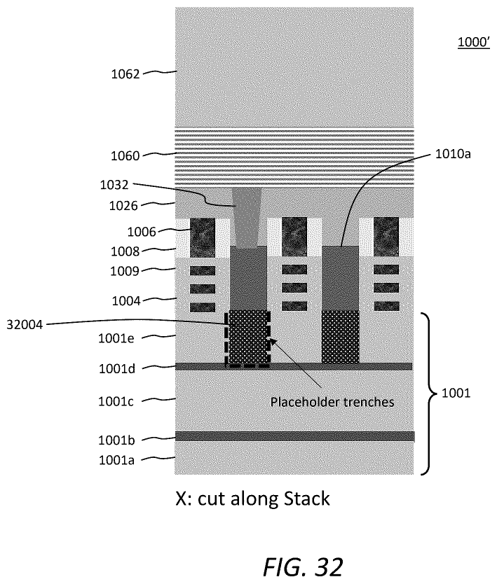

As highlighted above, the present techniques may advantageously be applied in a variety of different scenarios, including process flows for forming a semiconductor device 1000′ employing an optional placeholder for self-aligned contact to the source/drain regions 1010a and 1010b. See, for example, FIGS. 32-43.

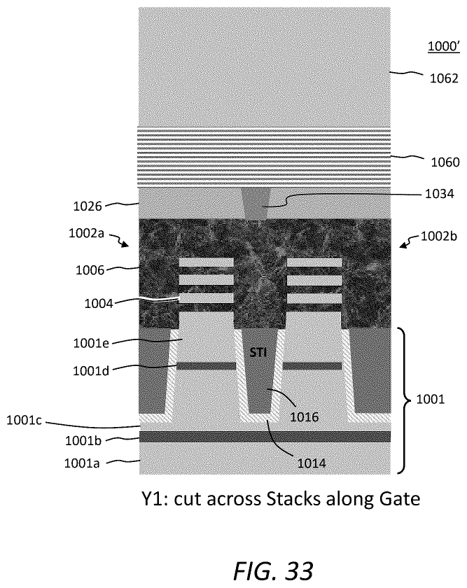

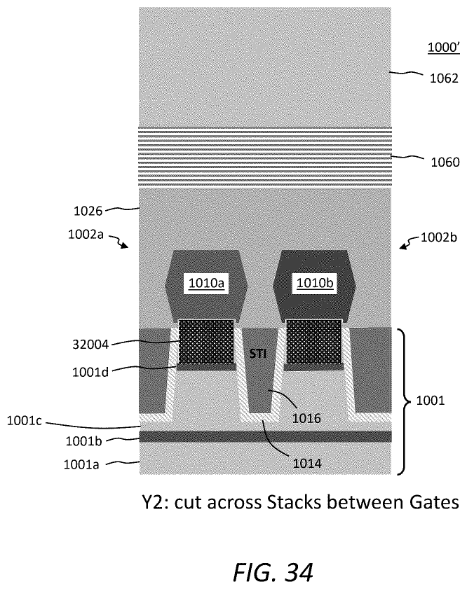

Namely, referring to FIG. 32 (an X cross-sectional view), FIG. 33 (a Y1 cross-sectional view) and FIG. 34 (a Y2 cross-sectional view), prior to forming the source/drain regions 1010a and 1010b, according to this alternative embodiment (optional) placeholders 32004 are formed in ‘placeholder trenches’ in the second semiconductor layer 1001e between the stacks of active layers 1004. Notably, like structures are numbered alike in the figures. According to an exemplary embodiment, the placeholders 32004 are formed from materials including, but not limited to, epitaxial SiGe and/or epitaxial III-V materials grown in the placeholder trenches. The process may then proceed as described in the previous example, except that the source/drain regions 1010a and 1010b are formed over these optional placeholders 32004.

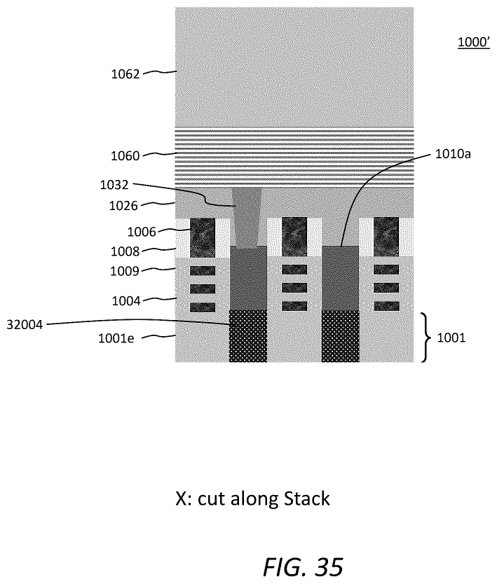

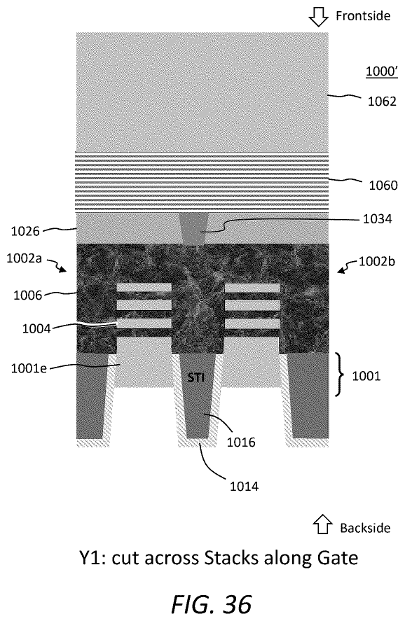

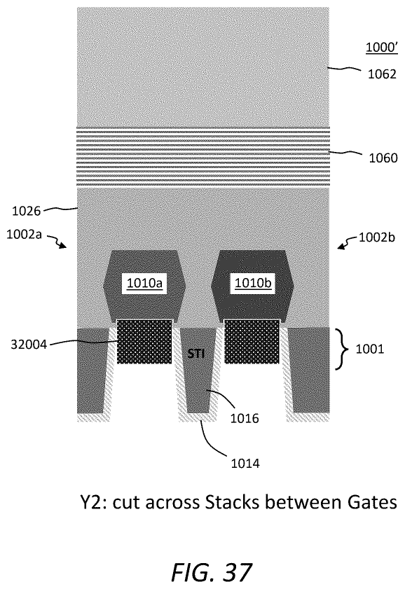

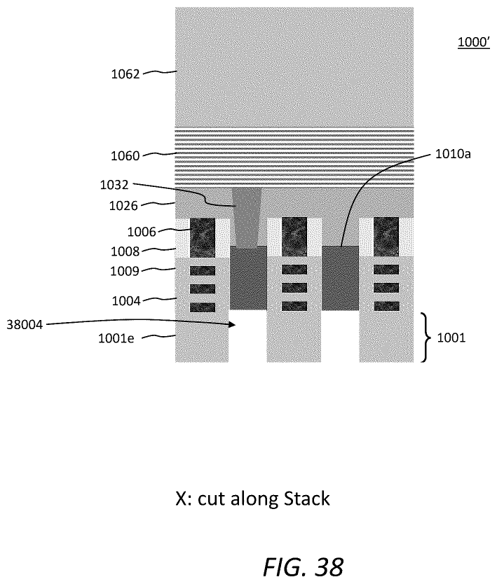

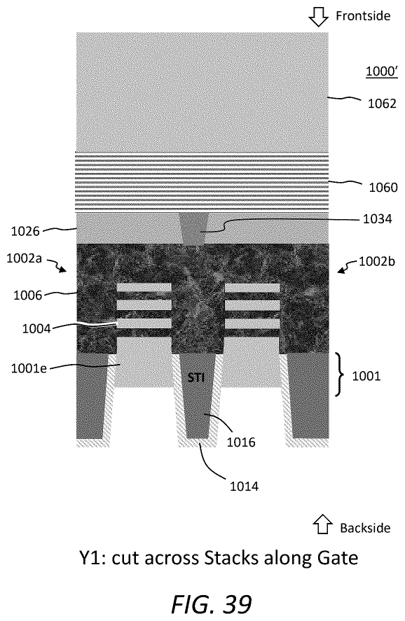

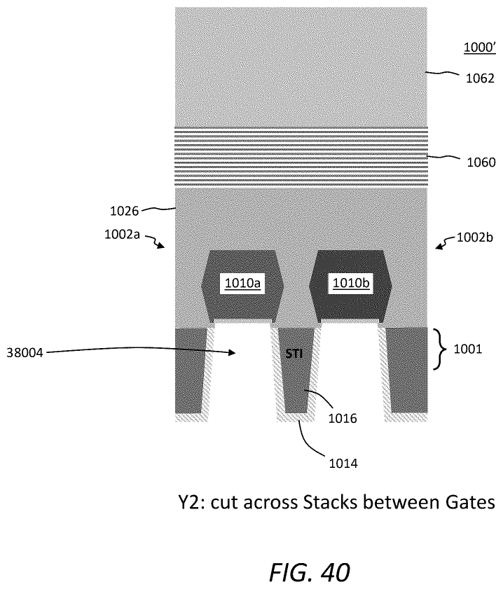

Advantageously, by employing the placeholders 32004, one can forgo the above-described backside contact lithography and etching processes involving the block mask 17004, the hardmask 17006, etc. Namely, referring to FIG. 35 (an X cross-sectional view), FIG. 36 (a Y1 cross-sectional view) and FIG. 37 (a Y2 cross-sectional view), removal of the substrate 1001a, the first etch stop layer 1001b (i.e., first interlayer), the first semiconductor layer 1001c, and the second etch stop layer 1001d (i.e., second interlayer), in the same manner as described above, exposes the placeholders 32004 from the backside of the wafer 1001. Referring to FIG. 38 (an X cross-sectional view), FIG. 39 (a Y1 cross-sectional view) and FIG. 40 (a Y2 cross-sectional view), backside removal of the (now-exposed) placeholders 32004 using, e.g., a SiGe-selective or III-V-selective etch as the case may be, creates contact trenches 38004 in the second semiconductor layer 1001e.

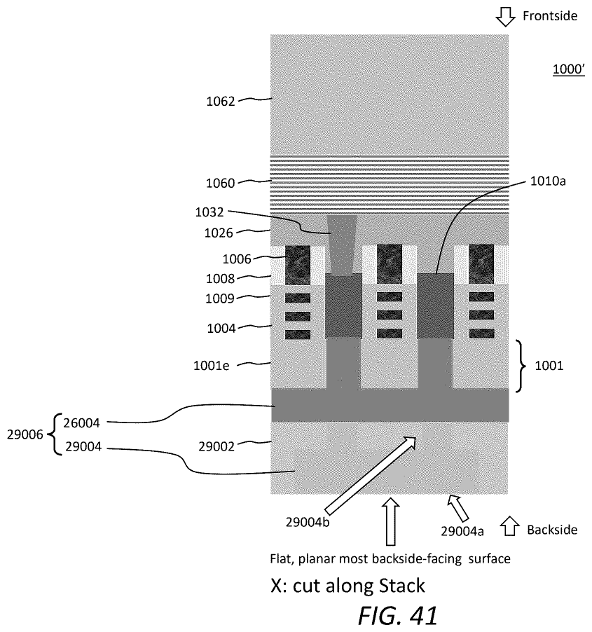

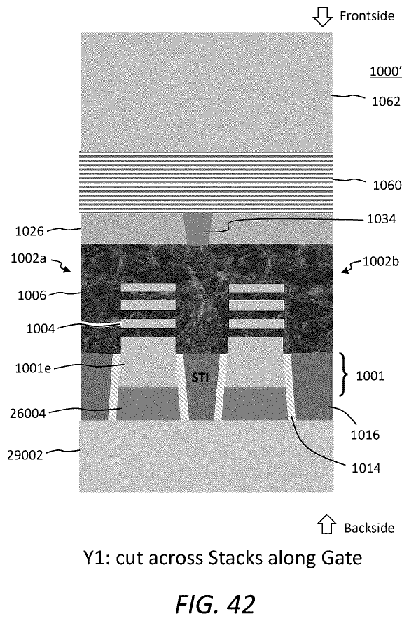

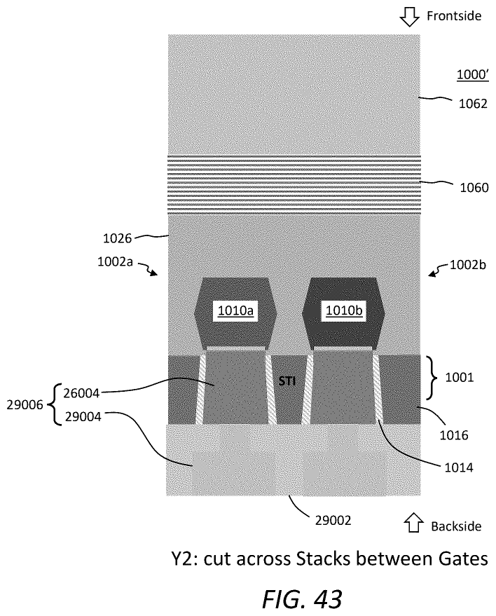

Referring to FIG. 41 (an X cross-sectional view), FIG. 42 (a Y1 cross-sectional view) and FIG. 43 (a Y2 cross-sectional view), the process may then proceed in the same manner as the previous example to form the backside contacts 26004 on the most backside-facing surface of the second semiconductor layer 1001e and within the contact trenches 38004 that directly contact the source/drain regions 1010a and 1010b, and to form the local wiring layer 29004 over and directly contacting the backside contacts 26004 to complete the semiconductor device 1000′. As above, the backside contacts 26004 and the local wiring layer 29004 together form the backside power distribution network 29006 of the semiconductor device 1000′ on the backside of the wafer 1001.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
at least one field-effect transistor (FET) on a frontside of a wafer, wherein the wafer comprises a semiconductor layer, and wherein a most backside-facing surface of the semiconductor layer is planar; and
a backside contact disposed on the most backside-facing surface of the semiconductor layer, wherein the backside contact directly contacts source/drain regions of the at least one FET.

2. The semiconductor device of claim 1, wherein the backside contact comprises:
a first portion having a top surface thereof which directly contacts and is coplanar with the most backside-facing surface of the semiconductor layer; and
second portions, contiguous with the first portion, that directly contact the source/drain regions of the at least one FET.

3. The semiconductor device of claim 1, wherein the backside contact comprises a contact metal selected from the group consisting of: tungsten, cobalt, ruthenium, aluminum, and combinations thereof.

4. The semiconductor device of claim 1, further comprising:
a local wiring layer disposed on the backside contact.

5. The semiconductor device of claim 4, wherein the local wiring layer comprises a metal selected from the group consisting of: copper, ruthenium, aluminum, and combinations thereof.

6. The semiconductor device of claim 1, wherein the semiconductor layer has a thickness of from about 25 nanometers to about 35 nanometers.

7. A semiconductor device, comprising:
at least one field-effect transistor (FET) on a frontside of a wafer, wherein the wafer comprises a semiconductor layer;
a backside contact disposed on the semiconductor layer, wherein a most backside-facing surface of the backside contact is planar, and wherein the backside contact directly contacts source/drain regions of the at least one FET; and
a local wiring layer disposed on the most backside-facing surface of the backside contact.

8. The semiconductor device of claim 7, wherein the backside contact comprises a contact metal selected from the group consisting of: tungsten, cobalt, ruthenium, aluminum, and combinations thereof.

9. The semiconductor device of claim 7, wherein the local wiring layer comprises a metal selected from the group consisting of: copper, ruthenium, aluminum, and combinations thereof.

10. The semiconductor device of claim 7, wherein the local wiring layer comprises:
a metal line; and
conductive vias that interconnect the metal line and the backside contact.

11. The semiconductor device of claim 7, wherein the semiconductor layer has a thickness of from about 25 nanometers to about 35 nanometers.

12. A method of fabricating a semiconductor device, the method comprising:
forming at least one field-effect transistor (FET) on a frontside of a wafer, wherein the wafer comprises: a substrate, a first etch stop layer disposed on the substrate, a first semiconductor layer disposed on the first etch stop layer, a second etch stop layer disposed on the first semiconductor layer, and a second semiconductor layer disposed on the second etch stop layer;
performing an etch from a backside of the wafer to remove the substrate, stopping on the first etch stop layer;
removing the first etch stop layer;
performing another etch from the backside of the wafer to remove the first semiconductor layer, stopping on the second etch stop layer;
removing the second etch stop layer to expose a most backside-facing surface of the second semiconductor layer which is planar; and
forming a backside contact on the most backside-facing surface of the second semiconductor layer which directly contacts source/drain regions of the at least one FET.

13. The method of claim 12, wherein the backside contact comprises a contact metal selected from the group consisting of: tungsten, cobalt, ruthenium, aluminum, and combinations thereof.

14. The method of claim 12, further comprising:
forming a local wiring layer on the backside contact.

15. The method of claim 14, wherein a most backside-facing surface of the backside contact is planar, and wherein the local wiring layer is formed on the most backside-facing surface of the backside contact.

16. The method of claim 14, wherein the local wiring layer comprises a metal selected from the group consisting of: copper, ruthenium, aluminum, and combinations thereof.

17. The method of claim 12, further comprising:
forming at least one placeholder in the second semiconductor layer; and
forming the source/drain regions of the at least one FET over the at least one placeholder.

18. The method of claim 17, further comprising:
removing the at least one placeholder from the backside of the wafer to form the backside contact in direct contact with the source/drain regions of the at least one FET.

19. The method of claim 17, wherein the first etch stop layer has a thickness T1 and the second etch stop layer has a thickness T2, and wherein T1>T2.

20. The method of claim 17, wherein the first semiconductor layer has a thickness t1 and the second semiconductor layer has a thickness t2, and wherein t1>t2.
